(19) United States
(12) Patent Application Publication
(10) Pub. No.: US 2012/0111404 A1
(43) Pub. Date: May 10, 2012

(54) THERMOSETTING ELECTRODE PASTE FIREABLE AT A LOW TEMPERATURE

(76) Inventors: Kun-ho Hwang, Hwaseong (KR); Yong-jun Jung, Hwaseong (KR); Min-soo Ko, Hwaseong (KR); Mee-hye Jeong, Hwaseong (KR)

(21) Appl. No.: 13/381,142

(22) PCT Filed: Jul. 16, 2010
(86) PCT No.: PCT/KR10/04646

§ 371 Date: Dec. 28, 2011

(30) Foreign Application Priority Data
Jul. 28, 2009 (KR) 10-2009-0068729
Sep. 17, 2009 (KR) 10-2009-0087987
Jul. 16, 2010 (KR) 10-2910-0068806

(51) Int. Cl. H01L 31/0224; H01B 1/00; H01B 1/02; H05K 1/09

(52) U.S. Cl. 136/256; 174/257; 252/500; 252/514

(57) ABSTRACT

There is provided a thermosetting electrode paste sinterable at a low temperature. The electrode paste in accordance with the present invention has superior adhesion, high resolution, low contact resistance, superior storage stability and electrical resistivity so that it is widely applicable to the fields of radio frequency identification tags, printing circuit boards, solar cells, etc.

### FIELD OF THE INVENTION

The present invention relates to a thermosetting electrode paste sinterable at a low temperature, and the electrode paste in accordance with the invention can exhibit superior adhesion, high resolution, low contact resistance, superior storage stability and electrical resistivity.

### BACKGROUND OF THE INVENTION

In the prior arts, electrode pastes have been prepared by mixing conductive powders, thermosetting resins such as epoxy or urethane, monomers, curing agents, and solvents. However, the electrodes obtained by curing such electrode pastes by heat showed poor cohesion onto ceramic substrates and silicon substrates. Meanwhile, in the case of polyisocyanates used for the production of prior electrode pastes, the urethane compounds which were generated from heat curing showed a slow reaction rate and thus required a long curing time and it further caused deterioration in cohesion with regard to ceramic substrates.

When amine-type curing agents were used, curing reaction might gradually occur during their storage period at a room temperature (25° C.) to cause a stability issue of increasing the viscosity of pastes. When epoxy resins or monomers were used, sudden contraction of pastes during heat curing reaction might resulted in cracks of pattern electrodes or scaling off from the substrates (or base board). Moreover, oxidation decomposition of resins might occur by heat energy (less than 200-300° C.) provided during the sintering procedures, thereby causing the drop-off of the electrodes.

### SUMMARY OF THE INVENTION

Accordingly, it is an object of the present invention to provide a thermosetting electrode paste sinterable at a low temperature, which has superior adhesion, high resolution, low contact resistance, superior storage stability and electrical resistivity and is thus widely applicable to the fields of radio frequency identification tags, printing circuit boards, solar cells, etc.

In order to achieve the objects, the present invention provides a thermosetting electrode paste sinterable at a low temperature, comprising:

(a) a conductive powder;

(b) a thermosetting oligomer;

(c) an initiator for thermosetting;

(d) a binder; and

(e) a solvent.

Further, the present invention provides an electrode formed by printing the thermosetting electrode paste sinterable at a low temperature onto a substrate and then drying and sintering it; and an electronic material comprising the thus prepared electrode.

The thermosetting electrode paste sinterable at a low temperature in accordance with the present invention has the following effects:

First, it exhibits superior electrical resistivity even at a low temperature (300° C. or under) due to its excellent degree of curing.

Second, it shows no diffusion of electrode linewidths since the curing reaction of the paste is carried out at a low drying temperature (less than 200° C.).

Third, it has superior adhesion to substrates at a low sintering temperature (less than 150-300° C.). In particular, when thiol or silane compounds in the paste are used, they are being wrapped around conductive powders in the form of —S— or —Si— and then, when heat is applied, their aromatic carbon rings come to break, thereby elevating the adhesion to the substrates.

Fourth, when it is used for the formation of electrodes for solar cells, it can reduce contact resistance in the formed electrodes because it is a glass frit-free paste.

Fifth, it can achieve a high aspect ratio due to the superior rheology properties of the paste.

Sixth, it shows little change in viscosity and in particular, since thiol or silane compounds in the paste are wrapped around the conductive powders, it exhibits good dispersion properties and storage stability.

Seventh, it shows high adhesive strength regardless of the texture of the substrates of polymers, glass, metals, ceramics, etc., and thus it is widely applicable to the fields of radio frequency identification tags, printing circuit boards, solar cells, etc.

### DETAILED DESCRIPTION OF THE INVENTION

In accordance with the present invention, internal stress which occurs by the contraction of electrode pastes during the formation of electrodes can be reduced by using thermosetting oligomers in preparing the electrode pastes, and the curing time can be shortened due to the thermosetting oligomers containing a large number of functional groups in comparison with monomers when the same amount of initiators are used. Moreover, an electrode coating film prepared with the electrode paste using the thermosetting oligomers has superior strength and dense structure, and possess excellent electrical conductivity as well as excellent substrate adhesion. Hence, the present invention is characterized by providing an electrode paste using oligomers, capable of enhancing its productivity due to the improvement of electrode quality and the shortening of the processing time.

Also, the electrode paste in accordance with the present invention can exhibit superior storage stability by comprising a thermosetting cationic or radical initiator so that curing reaction does not occur during storage at a room temperature (25° C.).

The thermosetting electrode paste sinterable at a low temperature in accordance with the present invention comprises:

(a) a conductive powder;

(b) a thermosetting oligomer;

(c) an initiator for thermosetting;

(d) a binder; and

(e) a solvent.

Preferably, the electrode paste of the present invention may comprise (a) 30-95 wt. % of the conductive powder; (b) 1-30 wt. % of the thermosetting oligomer; (c) 0.01-10 wt. % of the initiator for thermosetting; (d) 0.1-30 wt. % of the binder; and (e) a residual amount of the solvent.

The thermosetting electrode paste sinterable at a low temperature in accordance with the present invention may include pastes used for electronic devices comprising laminating layer structures, or materials for forming circuits such as wiring boards. Therefore, they include not only electrodes used for display devices and RFID devices but also electrical wirings used in these apparatuses.

Hereafter, each component will be described in detail.

(a) Conductive Powder

The powder used in the present invention may be those used for the preparation of conventional electrodes including gold (Au), silver (Ag), nickel (Ni), copper (Cu), etc., and they can be used without any special restrictions. Preferably, a silver powder may be used.

The conductive powder may have an average particle size of 0.05 to 10 μm, preferably, 0.1 to 5 μm. The conductive powder may be used in combination of two more kinds having various particle sizes and shapes and for example, a powder having a particle size of 0.05-2 μm and a powder having a particle size of 2-10 μm may be used in combination of two or more kinds. The shape of the conductive powder may be spherical, non-spherical, and plate-shape (flake-shape) and they may be used in combination of two or more kinds.

It may be advantageous to use a mixture of metal powders having various particle shapes and sizes in that the accuracy of printing can be increased and the fill factor (FF) of solar cells can be largely enhanced when applied to solar cells.

The conductive powder may be included in 30 to 95 wt. % of the solid components. When the amount of the metal powder is less than 30 wt. %, the viscosity of the paste is so low that it can be difficult to form an electrode pattern having high resolution when printed, and even though the electrode is formed on substrates, the diffusion of the electrode is so severe that the aspect ratio of the pattern can become very low. When the amount of the metal powder exceeds 95 wt. %, printing can be difficult due to its high viscosity and it is thus difficult to form the electrode on substrates and further, because the amount of organic substances is low, adhesive strength to the substrates is poor and thus, the drop-off of the electrodes may happen after drying.

(b) Thermosetting Oligomer

The thermosetting oligomer used in the present invention may include an acrylic oligomer, epoxy acrylate oligomer (epoxy acrylate copolymer), polyester acrylate oligomer, urethane acrylate oligomer, etc., and they may be used in alone or in combination. The weight average molecular weight of the acrylic oligomers may be suitably within the range of 500-1500.

The acrylic oligomers may include a multi-functional dipentaerythritol hexaacrylate oligomer, glycidyl methacrylate, (meth)acrylic acid, (meth)acrylic acid alkyl ester, polyethylene glycol (meth)acrylate, and propyleneglycol (meth)acrylate. Also, there may be used copolymers using pentaerythritol tri(meth)acrylate, pentaerythritol penta(meth)acrylate, and dipentaerythritol hexa(meth)acrylate.

For the mixtures comprising the acrylic oligomers, there can be used EBECRYL 1200 (product name, CYTEC Inc., US) and HSOL-500 (product name, Hansoo Chemical, Korea) which are commercially available in market.

For the mixtures comprising the epoxy acrylate oligomers, there can be used Miramer ME 2010 (product name, Miwon Commercial Co., Ltd., Korea), CN 150/80 (product name, Sartomer Co., US), EPA 1300 (product name, Hansoo Chemical, Korea) or 3020-A80 (product name, AGI Corporation., US) which are commercially available in market, or bisphenol A diacrylate oligomers having a high crosslinking density.

The thermosetting oligomers may be included in an amount of 1-30 wt. %. When the amount of the thermosetting oligomers is less than 1 wt. %, adhesion to the substrates may not be sufficient due to insufficient curing reaction, and when the amount of the oligomers is in excess of 30 wt. %, residual oligomers may function as an electrical insulator, thereby increasing contact resistance.

(c) Initiator for Thermosetting

The initiator for thermosetting used in the present invention may be a cationic or radical initiator.

The cationic initiators enable the thermosetting reaction of the oligomers to be carried out with high speed at low temperatures. Their specific examples may include ammonium/antimony hexafluoride, triarylsulfonium hexafluoroantimonate salt, triarylsulfonium hex afluoroantimonate, (tolycumyl) iodonium tetrakis(pentafluorophenyl)borate, bis(dodecylphenyl) iodonium hexafluoroantimonate, iodonium (4-methylphenyl)(4-(2-methylpropyl)phenyl)hexafluorophosphate, octyl diphenyliodonium hexafluoroantimonate, diaryliodonium salt, benzyl sulfonium salt, phenacylsulfonium salt, N-benzylpyridinium salt, N-benzylpyrazinium salt, N-benzylammonium salt, phenacyl sulfonium salt, N-benzylpyridinium salt, N-benzylpyrazinium salt, N-benzylammonium salt, phosphonium salt, hydrazinium salt, ammonium borate salt, triphenyl methyl chloride and a mixture thereof and preferably, there may be included ammonium/antimony hexafluoride, triarylsulfonium hexafluoroantimonate, triphenyl methyl chloride, etc.

The specific examples of the radical initiators may include peroxides such as benzoylperoxide, lauroylperoxide, diacetylperoxide, or di-tert-butylperoxide; hydroperoxides such as cumylhydroperoxide; and azo compounds such as azobisisobutyronitrile (AIBN) having a cyano (—CN) functional group, 2,2-azobis[2-methyl-N-(2-(1-hydroxybutyl))propionamide], 2,2-azobis[2-methyl-N-(2-hydroxyethyl)propionamide], 2,2-azobis[N-butyl-2-methylpropionamide], 2,2-azobis[N-cyclohexyl-2-methylpropionamide] and dimethyl-2,2-azobis(2-methylpropionate). Of them, azobis(cyclohexane-carbonitrile) compounds may be preferably used in that their curing reaction is carried out even at drying temperature (less than 100-200° C.) regions since they can be decomposed and reacted at 100° C. or higher, thereby suppressing the diffusion of electrode patterns and achieving high resolution patterns, and their curing reaction is suppressed at room temperatures so that they show no viscosity change under storage conditions of 25-40° C.

The initiator for thermosetting may be included in an amount of 0.01 to 10 wt. %. When the amount of the initiator for thermosetting is less than 0.01 wt. %, crosslinking with the oligomers may not be sufficient and thus, unreacted oligomers may cause a decrease in the degree of curing, and when the amount of the initiator is in excess of 30 wt. %, the remaining, unnecessary initiators may increase contact resistance and it is uneconomical as well.

(d) Binder

The binder used in the present invention may include cellulose derivatives such as ethyl cellulose, methyl cellulose, nitrocellulose and hydroxycellulose, and acrylic resins of isobutylmethacrylate, n-butyl methacrylate, or a copolymer thereof.

Also, there may be used commercially available acrylic resins such as ELVACITE 2045 (product name, ELVACITE Inc., US), ELVACITE 2046 (product name, ELVACITE Inc., US)

The binder may be included in an amount of 0.1-30 wt. % in the present invention. When the amount of the binder is less than 0.1 wt. %, printing performance is so poor that it may be difficult to form electrodes and adhesion to substrates might not be good. When the amount of the binder exceeds 30 wt. %, an increase in residual amounts of the binder after sintering causes a decrease in the degree of cohesion between the conductive powders, thereby reducing resistivity and deteriorating the efficiency of the electrodes by increasing contact resistance in solar cells.

(e) Solvent

The components (a) to (d), when used, may be mixed and dispersed in the solvent.

The applicable solvent may include butyl carbitol acetate, butyl carbitol, butyl cellusolve, propyleneglycol monomethylether, dipropyleneglycol monomethylether, propyleneglycol monomethyletherpropionate, ethyletherpropionate, terpineol, texanol, propyleneglycol monomethyletheracetate, dimethylamino formaldehyde, methylethylketone, gammabutyrolactone, ethyllactate, ethyleneglycol, N-methyl pyrollidone, N-ethyl pyrollidone, N-butyl pyrollidone, tetrahydrofurane and cellusolve derivatives and they may be used alone or in combination. Preferably, there may be used butyl carbitol acetate, terpineol or a mixture thereof.

The solvent may be included in a residual amount except the components (a) to (d).

(f) Adhesion Promoter

The electrode paste in accordance with the present invention may further optionally comprise an adhesion promoter, preferably thiol or silane aromatic carbon compounds in addition to the above components. The adhesion promoters are being bonded to the surface of the conductive powder in the paste in the form of —S— or —Si— and then, when heat (low temperature: less than 200° C.) is applied, their aromatic carbon rings come to break, thereby being chemically bonded to the substrate to elevate adhesion. Accordingly, there is no need to modify the surface of the substrate in a separate way, and before heat is applied, it has good dispersion ability in the electrode and keeps stable status at a room temperature.

The specific examples of the adhesion promoter may include thiol compounds such as butanethiol, pentanethiol and a mixture thereof; alkoxy silane compounds such as vinyltrimethoxysilane, vinyltriethoxysilane, vinylbutylenetriethoxysilane, vinyltri(beta-methoxy)silane, vinyltri(beta-ethoxy)silane, acryloxypropyltrimethoxysilane, acryloxypropyltriethoxysilane, acryloxypropylmethyldimethoxysilane, gamma-methacryloxypropyltrimethoxysilane, gamma-methacryloxypropyltriethoxysilane, gamma-methacryloxypropylmethyldimethoxysilane, gamma-methacryloxypropylmethyldiisopropoxysilane, gamma-methacryloxycarbitoltrimethoxysilane tetramethoxysilane, tetraethoxysilane, tetrapropoxysilane, tetraisopropoxysilane, tetra-n-butoxysilane, tetra-sec-butoxysilane, tetra-tert-butoxysilane, methyltrimethoxysilane, methyl triethoxysilane, methyltributoxysilane, ethyltrimethoxysilane, ethyltriisopropoxysilane, ethyltributoxysilane, butyltrimethoxysilane, phenyltrimethoxysilane, 3-methyltrimethoxysilane, dimethyldimethoxysilane, diphenyldimethoxysilane, dibutyldimethoxysilane, trimethylmethoxysilane, trimethylethoxysilane, tributylmethoxysilane, tributylethoxysilane, trifluoromethyltrimethoxysilane, trifluoromethyltriethoxysilane, trifluoropropyltrimethoxysilane, trifluoropropyltriethoxysilane, nonafluorobutylethyltrimethoxysilane, nonafluorobutylethyltriethoxysilane, nonafluorohexyltrimethoxysilane, nonafluorohexyltriethoxysilane, tridecafluorooctyltrimethoxysilane, tridecafluorooctyltriethoxysilane, heptadecafluorodecyltrimethoxysilane, heptadecafluorodecyltriethoxysilane, heptadecafluorodecyltriisopropylsilane, 3-trimethoxysilylpropylpentadecafluorooctate, 3-triethoxysilylpropylpentadecafluorooctate, 3-trimethoxysilylpropylpentadecafluorooctiamide, 3-triethoxysilylpropylpentadecafluoroocticamide, 2-trimethoxysilylethylpentadecafluorodecyl sulfide, 2-triethoxysilylethylpentadecafluorodecylsulfide, pentafluorophenyltrimethoxysilane, pentafluorophenyltriethoxysilane, 4-(perfluorotolyl)trimethoxysilane, 4-(perfluorotolyl)triethoxysilane, dimethoxybis(pentafluorophenyl)silane, diethoxybis(4-pentafluorotolyl)silane, 2-(3,4-epoxycyclohexyl)ethyltrimethoxysilane and a mixture thereof; and silane compounds having at least one substituent of a vinyl group, epoxy group, methacryl group, mercapto group or isocyanate group, instead of the alkoxy groups.

The adhesion promoter may be included in an amount of 0.1-30 wt. % in the present invention. When the amount of the adhesion promoter is less than 0.1 wt. %, the intended effects are not achieved, and when it exceeds 30 wt. %, adhesion is not increased any more.

(g) Monomer

The electrode paste in accordance with the present invention may further optionally comprise a monomer.

The monomers may be (meth)acrylic monomers including methacrylate monomers, or epoxy monomers, or a mixture thereof and more particularly, there may be preferably used at least one selected from the group consisting of methylmethacrylate, ethylmethacrylate, tricyclodecandimethanol dimethacrylate, methylacrylate, ethylacrylate, isopropylacrylate, isobornylacrylate, acryloyloxyethyl succinate, phenoxyethyleneglycol acrylate, phenoxyethylacrylate, 2-hydroxyethyl acrylate, hydroxypropyl acrylate, diethylene glycol dimethacrylate, aryl methacrylate, ethylene glycol dimethacrylate, diethylene glycol dimethacrylate, triethylene glycol dimethacrylate, tetraethylene glycol dimethacrylate, glycerol dimethacrylate, pentamethyl piperidyl methacrylate, lauryl acrylate, tetrahydroperfuryl acrylate, hydroxy ethyl acrylate, hydroxy propyl acrylate, isobornyl acrylate, hexanediol diacrylate, 1,6-hexanediol diacrylate, diethylene glycol diacrylate, tripropylene glycol diacrylate, dipropylene glycol diacrylate, polyethylene glycol diacrylate, neopentyl glycol diacrylate, trimethylolpropane triacrylate, neopentyl glycol diacrylate, ethoxylated trimethylolpropane triacrylate, propoxylated trimethylolpropane triacrylate, trimethylolpropane epoxylate triacrylate, trimethylolpropane trimethacrylate, pentaerythritol triacrylate, pentaerythritol tetraacrylate, dipentaerythritol hexaacrylate, glycerinpropoxylated triacrylate and methoxyethyleneglycol acrylate.

The monomers may be included preferably in an amount of 20 wt. % or less. When they are present out of the above amount ranges, the monomers that do not participate in reaction remain as impurities and can reduce curing speed. Preferably, they may be included in an amount of 0.01 to 15 wt. %.

(h) Other Additives

In addition to the above components, the electrode paste in accordance with the present invention may further other additives that may be usually included in pastes, if necessary. For example, the additives may include a thickening agent, stabilizer, dispersing agent, defoaming agent, surfactant and a mixture thereof, and they may be each included in an amount of 0.1-5 wt. %.

The electrode paste of the present invention having the above compositions may be obtained by combining the essential components and optional components in a desired ratio and evenly dispersing them using a blender or a mill such as a 3-axial roll.

Preferably, the paste of the present invention may have a viscosity of 1 to 300 Pa.S when measured using Brookfield HBT Viscometer at #51 spindle with the condition of shear rate of 3.84 sec⁻¹ under the temperature of 25° C.

The electrode paste in accordance with the present invention has no internal stress which normally occurs by the contraction of pastes so that it has superior adhesion to substrates and it can be quickly cured at a drying temperature (less than 100-200° C.). thereby causing no diffusion of the electrode and thus can show high resolution. Furthermore, since it has superior degree of curing at a drying temperature (less than 200° C.) superior electrical resistivity properties can be achieved even at a low temperature (300° C. or under). Therefore, the electrode paste of the present invention is applicable to a wide variety of fields. Of them, when it is applied to the field of solar cells, it can reduce contact resistance because as a glass frit free paste, it has a high crowding of silver powder after sintering, and the effects can be elevated especially when applied to amorphous/crystalline silicon heterojunction solar cells.

Also, the invention provides an electrode formed by printing the electrode paste onto a substrate and then drying and sintering it; and electronic materials comprising the thus prepared electrode. The electronic materials may be radio frequency identification tags, printing circuit boards, or solar cells and preferably, the electronic materials may be solar cells and more preferably, amorphous/crystalline silicon heterojunction solar cells.

When forming the electrode for electronic materials in accordance with the present invention, it is noted that substrates, printing, drying and sintering methods that have been conventionally used for the preparation of electrodes for electronic materials can be used except for the use of the thermosetting electrode paste sinterable at a low temperature of the present invention. For example, the substrates may be a Si substrate; the electrodes may be a front or back electrode for solar cells; the printing may be screen printing; and the drying can be carried out at 100-250° C. The sintering may be preferably a low temperature sintering where it is carried out for 10 min. to 60 min. at low temperatures of 150-300° C., and the printing may be preferably conducted in a thickness of 10 to 50 μm.

The thus formed electrode of the present invention has high accuracy, and the solar cells prepared using the electrode pastes in accordance with the present invention have high efficiency and high resolution and they are particularly suitable for low-temperature sintering, and their effects can be more increased when applied to amorphous/crystalline silicon heterojunction solar cells.

For better understanding of the present invention, preferred examples follow. The following examples are intended to merely illustrate the invention without limiting the scope of the invention.

### EXAMPLES

### Examples 1 to 6 and Comparative Examples 1 and 2

The electrode pastes were prepared by blending the components in amounts (wt. %) set forth in Table 1 below and then, mixing and dispersing them using a 3-roll mill.

TABLE 1

| | | Ex. | Ex. | Ex. | Ex. | Ex. | Ex. | Com. | Com. |
|---|---|---|---|---|---|---|---|---|---|
| | | 1 | 2 | 3 | 4 | 5 | 6 | Ex. 1 | Ex. 2 |
| Conductive | Silver Powder | 30 | 70 | 85 | 85 | 70 | 85 | 30 | 85 |
| Powder | | | | | | | | | |
| Binder | Cellulose | 6 | 6 | 2 | 2 | 6 | 2 | — | 2 |
| | Resin | | | | | | | | |
| | Acrylic Resin | 4 | — | 1 | — | — | 1 | — | — |
| | Epoxy Resin | | | | | | | 10 | 5 |
| Thermosetting | Acrylic | 10 | 7 | 5 | 6 | 7 | 5 | — | — |
| Oligomer | Oligomer and | | | | | | | | |
| | Epoxyacrylate | | | | | | | | |
| | Oligomer | | | | | | | | |
| Monomer | Acrylic | — | — | — | — | — | — | 10 | — |
| | Monomer | | | | | | | | |
| Curing Agent | Amine-Type | — | | — | — | — | — | 1 | 0.5 |
| Initiator for | Radical | 1 | — | — | 0.5 | 1 | 1 | — | — |
| Thermosetting | Initiator 1 | | | | | | | | |
| | Radical | — | 0.7 | — | — | — | — | — | — |
| | Initiator 2 | | | | | | | | |
| | Cationic | — | — | 0.5 | — | — | — | 1 | — |
| | Initiator | | | | | | | | |
| Solvent | Terpineol | 25 | 7.5 | 2 | 3 | 13 | 3 | 25 | 4 |
| | Butyl Carbitol | 20 | 7.5 | 3 | 2 | 2 | 2.5 | 20 | 2 |
| | Acetate | | | | | | | | |
| Adhesion | Thiol | — | — | — | — | 1 | — | — | — |
| Promoter | Compound | | | | | | | | |
| | Silane | — | — | — | — | — | 0.5 | — | — |
| | Compound | | | | | | | | |
| Additives | Defoaming | 2 | 0.3 | 0.5 | 0.5 | — | — | 2 | 0.5 |
| | Agent | | | | | | | | |
| | Dispersion | 1 | 1 | 1 | 1 | — | — | 1 | 1 |
| | Agent | | | | | | | | |

The details of the components set forth in Table 1 are as follows:
Silver Powder: Silver powder in plate shape having the average particle size of 2.5 μm.
Cellulose Resin: Hydroxy cellulose
Acrylic Resin: ELVACITE 2045
Epoxy Resin: Bisphenol A resin
Acrylic Oligomer and Epoxyacrylate Oligomer: EBECRYL-1200 and Miramer ME 2010 in the ratio of 4:1 by weight
Acrylic Monomer: TMPTA and HDDA in the ratio of 7:3 by weight
Amine-Type Curing Agent: Polyamide
Radical Initiator 1: Azobis initiator (Azobisisobutyronitrile)
Radical Initiator 2: Benzoylperoxide
Cationic Initiator: Triphenyl methylchloride
Thiol Compound: Butanediol:Pentanediol=5:5 by weight
Silane Compound: 2-(3,4-epoxycyclohexyl)ethyltrimethoxysilane
Defoaming Agent: Silicon-type defoaming agent
Dispersion Agent: Alkylol ammonium salt

The electrode pastes prepared in Examples 1 to 6, and Comparative Examples 1 and 2 were each measured with regard to resistivity, substrate adhesion, resolution, contact resistance, aspect ratio and viscosity change rate in accordance with the following methods. The results are shown in Table 2 below.

1) Resistivity (*10⁻⁵Ω·cm)

After the electrode pastes were printed onto substrates and then cured for 15 min. at 180° C., for 15 min. at 200° C., and for 15 min. at 220° C., their resistivities were measured using a 4-point probe.

2) Substrate Adhesion

In accordance with grid adhesion test (ASTM D3359), 100 grid patterns were added to the pastes that were printed and cured on the substrate, using a crosscut knife. Then, a tape specialized in metal adhesion (3M, #610) was attached thereto and then peeled off, and then the number of the peeled-off grids was counted.

3) Resolution(μm)

The pastes were printed with resolution masks having the pattern of linewidth of 60-110 μm and dried and sintered. Resolution was recorded in case that the linewidth change rate of the pattern was within 10%.

4) Contact Resistance (mΩ·cm)

The electrode pastes were printed onto the back side of solar cells by a screen printing method and dried using a hot air-type dry oven. Then, the electrode pattern of linewidth of 110 μm was printed onto the front side and dried for 5 min at 160° C. The thus prepared cells were sintered for 15 min at 220° C. using a sintering furnace. The thus prepared cells were measured using Correscan with regard to their contact resistance.

5) Aspect Ratio (%)

The height of the electrode patterns and the pattern linewidth after sintering were each measured with SEM and the ratio of the pattern height/pattern linewidth was calculated to see aspect ratio (%).

6) Viscosity Change Rate (%)

After the electrode pastes were stored at 25° C. for one month, their viscosity change was measured using Brookfield HBT Viscometer at #51 spindle with the condition of shear rate of 3.84 sec-1 under the temperature of 25° C. to observe viscosity change rate.

TABLE 2

| | | Ex. | Ex. | Ex. | Ex. | Ex. | Ex. | Com. Ex. | Com. Ex. |
|---|---|---|---|---|---|---|---|---|---|
| | | 1 | 2 | 3 | 4 | 5 | 6 | 1 | 2 |
| Resistivity | Curing at | 4.77 | 4.18 | 3.62 | 2.31 | 2 | 2.45 | 33.4 | 10.7 |
| (*10⁻⁵ | 180° C. for | | | | | | | | |
| Ω · cm) | 15 min. | | | | | | | | |
| | Curing at | 2.30 | 2.38 | 1.94 | 1.45 | 1.43 | 1.78 | 30.1 | 4.33 |
| | 200° C. for | | | | | | | | |
| | 15 min. | | | | | | | | |
| | Curing at | 2.09 | 1.80 | 0.94 | 0.89 | 1 | 1.22 | 14.2 | 3.2 |
| | 220° C. for | | | | | | | | |
| | 15 min. | | | | | | | | |
| Substrate | Tape | 0 | 0 | 0 | 0 | 0 | 0 | 10 | 30 |
| Adhesion | Adhesion | | | | | | | | |
| | (ASTM | | | | | | | | |
| | D3359) | | | | | | | | |
| Resolution | Linewidth | 60 | 60 | 70 | 70 | 70 | 70 | 90 | 90 |
| (μm) | change rate | | | | | | | | |
| | after | | | | | | | | |
| | printing | | | | | | | | |
| | within 10% | | | | | | | | |
| Contact | Solar cell | 6 | 7 | 7 | 7 | 7 | 7 | 9 | 9 |
| Resistance | evaluation | | | | | | | | |
| (m Ω · cm) | | | | | | | | | |
| Aspect | Pattern | 17.23 | 27.45 | 30.8 | 31.06 | 30 | 31.06 | 7.11 | 14.6 |
| Ratio (%) | height/pattern | | | | | | | | |
| | line | | | | | | | | |
| | width ratio | | | | | | | | |
| | after curing | | | | | | | | |
| Viscosity | After | 2.19 | 3.8 | 5.02 | 4.66 | 3 | 4 | Completely | Completely |
| Change | storage at | | | | | | | cured | cured |
| Rate (%) | 25° C. for 1 | | | | | | | | |
| | month | | | | | | | | |

As shown in Table 2, the electrode pastes comprising the oligomers according to the present invention of Examples 1 to 6 exhibited remarkably enhanced effects in aspects of electrical resistivity, substrate adhesion, resolution, contact resistance, aspect ratio and viscosity change rate, in comparison with the electrode pastes of Comparative Examples 1 and 2 comprising no oligomers.

Although the invention is described in connection with preferred embodiments in the above, it is to be understood that various modifications and alterations can be made by those skilled in the pertinent art within the scope of the invention defined by the accompanying claims.

The thermosetting electrode paste sinterable at a low temperature in accordance with the present invention has the following effects:

First, it exhibits superior electrical resistivity even at a low temperature (300° C. or under) due to its excellent degree of curing.

Second, it shows no diffusion of electrode linewidths since the curing reaction of the paste is carried out at a low drying temperature (less than 200° C.).

Third, it has superior adhesion to substrates at a low sintering temperature (less than 150-300° C.). In particular, when thiol or silane compounds in the paste are used, they are being wrapped around conductive powders in the form of —S— or —Si— and then, when heat is applied, their aromatic carbon rings come to break, thereby elevating the adhesion to the substrates.

Fourth, when it is used for the formation of electrodes for solar cells, it can reduce contact resistance in the formed electrodes because it is a glass frit-free paste.

Fifth, it can achieve a high aspect ratio due to the superior rheology properties of the paste.

Sixth, it shows little change in viscosity and in particular, since thiol or silane compounds in the paste are wrapped around the conductive powders, it exhibits good dispersion properties and storage stability.

Seventh, it shows high adhesive strength regardless of the texture of the substrates of polymers, glass, metals, ceramics, etc., and thus it is widely applicable to the fields of radio frequency identification tags, printing circuit boards, solar cells, etc.

1. A thermosetting electrode paste sinterable at a low temperature comprising
(a) a conductive powder;
(b) a thermosetting oligomer;
(c) an initiator for thermosetting;
(d) a binder; and
(e) a solvent.

2. The thermosetting electrode paste sinterable at a low temperature of claim 1 comprising
(a) 30-95 wt. % of the conductive powder;
(b) 1-30 wt. % of the thermosetting oligomer;
(c) 0.01-10 wt. % of the initiator for thermosetting;
(d) 0.1-30 wt. % of the binder; and
(e) a residual amount of the solvent.

3. The thermosetting electrode paste sinterable at a low temperature of claim 1 wherein the conductive powder is a silver powder.

4. The thermosetting electrode paste sinterable at a low temperature of claim 1 wherein the thermosetting oligomer is selected from the group consisting of an acrylic oligomer, epoxy acrylate oligomer, urethane acrylate oligomer, polyester acrylate oligomer and a mixture thereof.

5. The thermosetting electrode paste sinterable at a low temperature of claim 1 wherein the initiator for thermosetting is a cationic or radical initiator.

6. The thermosetting electrode paste sinterable at a low temperature of claim 1 wherein the initiator for thermosetting is an azobis compound.

7. The thermosetting electrode paste sinterable at a low temperature of claim 1 wherein the binder is a cellulose derivative or acrylic resin.

8. The thermosetting electrode paste sinterable at a low temperature of claim 1 wherein the electrode paste further comprises an adhesion promoter.

9. The thermosetting electrode paste sinterable at a low temperature of claim 8 wherein the adhesion promoter is selected from the group consisting of butanethiol, pentanethiol, vinyltrimethoxysilane, vinyltriethoxysilane, vinylbutylenetriethoxysilane, vinyltri(beta-methoxy)silane, vinyltri(beta-ethoxy)silane, acryloxypropyltrimethoxysilane, acryloxypropyltriethoxysilane, acryloxypropylmethyldimethoxysilane, gamma-methacryloxypropyltrimethoxysilane, gamma-methacryloxypropyltriethoxysilane, gamma-methacryloxypropylmethyldimethoxysilane, gamma-methacryloxypropylmethyldiisopropoxysilane, gamma-methacryloxycarbitoltrimethoxysilane tetramethoxysilane, tetraethoxysilane, tetrapropoxysilane, tetraisopropoxysilane, tetra-n-butoxysilane, tetra-sec-butoxysilane, tetra-tert-butoxysilane, methyltrimethoxysilane, methyltriethoxysilane, methyltributoxysilane, ethyltrimethoxysilane, ethyltriisopropoxysilane, ethyltributoxysilane, butyltrimethoxysilane, phenyltrimethoxysilane, 3-methyltrimethoxysilane, dimethyldimethoxysilane, diphenyldimethoxysilane, dibutyldimethoxysilane, trimethylmethoxysilane, trimethylethoxysilane, tributylmethoxysilane, tributylethoxysilane, trifluoromethyltrimethoxysilane, trifluoromethyltriethoxysilane, trifluoropropyltrimethoxysilane, trifluoropropyltriethoxysilane, nonafluorobutylethyltrimethoxysilane, nonafluorobutylethyltriethoxysilane, nonafluorohexyltrimethoxysilane, nonafluorohexyltriethoxysilane, tridecafluorooctyltrimethoxysilane, tridecafluorooctyltriethoxysilane, heptadecafluorodecyltrimethoxysilane, heptadecafluorodecyltriethoxysilane, heptadecafluorodecyltriisopropylsilane, 3-trimethoxysilylpropylpentadecafluorooctate, 3-triethoxysilylpropylpentadecafluorooctate, 3-trimethoxysilylpropylpentadecafluoroocticamide, 3-triethoxysilylpropylpentadecafluoroocticamide, 2-trimethoxysilylethylpentadecafluorodecylsulfide, 2-triethoxysilylethylpentadecafluorodecylsulfide, pentafluorophenyltrimethoxysilane, pentafluorophenyltriethoxysilane, 4-(perfluorotolyl)trimethoxysilane, 4-(perfluorotolyl)triethoxysilane, dimethoxybis(pentafluorophenyl) silane, diethoxybis(4-pentafluorotolyl)silane, 2-(3,4-epoxycyclohexyl)ethyltrimethoxysilane and a mixture thereof, and silane compounds having at least one of a vinyl group, epoxy group, methacryl group, mercapto group or isocyanate group, instead of the alkoxy groups.

10. The thermosetting electrode paste sinterable at a low temperature of claim 8 wherein the electrode paste comprises the adhesion promoter in an amount of 0.1-30 wt. %.

11. The thermosetting electrode paste sinterable at a low temperature of claim 1 wherein the electrode paste further comprises an acrylic monomer.

12. The thermosetting electrode paste sinterable at a low temperature of claim 1 wherein the electrode paste further comprises an additive selected from the group consisting of a thickening agent, stabilizer, dispersing agent, defoaming agent, surfactant, and a mixture thereof.

13. An electrode formed by printing the electrode paste according to claim 1 onto a substrate and then drying and sintering it.

14. An electronic material comprising the electrode of claim 13.

15. The electronic material of claim 14 wherein the electronic material is a solar cell.

16. The electronic material of claim 15 wherein the solar cell is an amorphous/crystalline silicon heterojunction solar cell.
